(19) United States
(12) Patent Application Publication
(10) Pub. No.: US 2006/0232919 A1
(43) Pub. Date: Oct. 19, 2006

(54) Plasma display module

(76) Inventor: Kwang-Jin Jeong, Suwon-si (KR)

Correspondence Address: LEE & MORSE, P.C., 3141 FAIRVIEW PARK DRIVE, SUITE 500, FALLS CHURCH, VA, 22042, US

(21) Appl. No.: 11/384,420

(22) Filed: Mar. 21, 2006

(30) Foreign Application Priority Data
Apr. 13, 2005 (KR) 10-2005-0030714

(51) Int. Cl. G06F 1/16; H05K 7/00

(52) U.S. Cl. 361/681

(57) ABSTRACT

A plasma display module includes a plasma display panel for displaying a visible image, a chassis supporting the plasma display panel and having at least one hole therein, and at least one heat dissipating fan disposed to face the at least one hole.

### BACKGROUND OF THE INVENTION

1. Field of the Invention

The present invention relates to a plasma display module. More particularly, the present invention relates to a plasma display module configured to efficiently dissipate heat.

2. Description of the Related Art

Plasma display modules, which display images using a gas discharge phenomenon, have recently attracted much attention since they provide a number of desirable characteristics including, e.g., wide viewing angles, slim form factors, high image quality, large display areas, etc.

In a typical plasma display module, the gas discharge is generated in a discharge cell, having a discharge gas therein, of a plasma display panel. The gas discharge may be produced by a DC or AC voltage applied to electrodes arranged in the plasma display panel. The plasma display panel may include two thin flat panels and a phosphor coated in each discharge cell, which is excited to emit visible light by ultraviolet light emitted from the discharge gas, thereby displaying a visible image.

The plasma display module uses a discharge mechanism for applying a high voltage to the discharge cell to generate the discharge and emit light. Accordingly, when the plasma display module is in use, a large amount of heat is generated in the discharge cells of the plasma display panel.

Heat generated from the plasma display panel increases the temperature of the plasma display panel, which may degrade the performance of the phosphors in the plasma display panel and, accordingly, the image quality. Further, the life span of the plasma display module may be reduced by excessive heat.

In order to dissipate heat generated from the plasma display panel to the outside, a heat dissipating sheet having a high thermal conductivity may be interposed between the plasma display panel and a chassis supporting the plasma display panel. Accordingly, heat generated by the plasma display panel may be transferred to the chassis by way of the heat dissipating sheet, which serves as a thermal conductive medium. The heat may then be dissipated from the chassis to the surrounding environment. However, the heat dissipation from the chassis to the surrounding environment is conventionally achieved using passive heat transfer, which may be insufficient for those plasma display panels that generate significant amounts of heat.

### SUMMARY OF THE INVENTION

The present invention is therefore directed to a plasma display module, which substantially overcomes one or more of the problems due to the limitations and disadvantages of the related art.

It is therefore a feature of an embodiment of the present invention to provide a plasma display module configured to efficiently dissipate heat from a plasma display panel to the outside using forced ventilation.

It is therefore another feature of an embodiment of the present invention to provide a plasma display module that achieves forced ventilation using one or more fans disposed along holes in a chassis of the plasma display module.

It is therefore a further feature of the present invention to provide a plasma display module configured to control the rotational speed of a fan so as to effect cooling while reducing unnecessary power consumption and noise generation.

At least one of the above and other features and advantages of the present invention may be realized by providing a plasma display module including a plasma display panel for displaying a visible image, a chassis supporting the plasma display panel and having at least one hole therein, and at least one heat dissipating fan disposed to face the at least one hole.

The plasma display module may further include a driving circuit unit for generating electrical signals for driving the plasma display panel, wherein the driving circuit unit is disposed on a surface of the chassis opposite to the plasma display panel, and the at least one hole is formed in a portion of the chassis in which the driving circuit unit is not disposed.

The heat dissipating fan may be disposed substantially in parallel with the chassis. The heat dissipating fan may be disposed to circulate air in a space defined between the chassis and the plasma display panel. The heat dissipating fan may be disposed to send the air from an opposite side of the chassis to the space. The heat dissipating fan is disposed to send the air from the space to an opposite side of the chassis. The plasma display module may include at least two heat dissipating fans, at least one of the two heat dissipating fans may be disposed to send air from an opposite side of the chassis to the space, and at least one other of the two heat dissipating fans may be disposed to send air from the space to the opposite side of the chassis.

The plasma display module may further include a thermally conductive heat dissipating sheet interposed between the plasma display panel and the chassis and arranged such that the at least one heat dissipating fan can circulate air between the heat dissipating sheet and the chassis. One surface of the heat dissipating sheet may contact the plasma display panel and the other surface thereof may not contact the chassis, such that air circulated by the fan can travel across the other surface.

The plasma display module may further include a sensor and a rotational speed controller configured to receive data from the sensor and control a rotational speed the heat dissipating fan. The sensor and the rotational speed controller may be part of the heat dissipating fan. The heat dissipating fan may further include a finned heat sink. The sensor may be a temperature sensor. The rotational speed controller may be configured to decrease the rotational speed of the heat dissipating fan when the temperature sensor senses a decreasing temperature. The sensor may be a noise sensor. The rotational speed controller may be configured to decrease the rotational speed of the heat dissipating fan when the noise sensor senses a lower level of noise. The rotational speed controller may be configured to continuously vary the rotational speed of the heat dissipating fan between a first speed and a second speed. The rotational speed controller may be configured to set the rotational speed of the heat dissipating fan to one of at least three predetermined rotational speeds.

### BRIEF DESCRIPTION OF THE DRAWINGS

The above and other features and advantages of the present invention will become more apparent to those of ordinary skill in the art by describing in detail exemplary embodiments thereof with reference to the attached drawings in which

FIG. 1 illustrates a perspective view of a plasma display module according to an embodiment of the present invention;

FIG. 2 illustrates a partial cross-sectional view taken along line II-II shown in FIG. 1;

FIG. 3 illustrates a partial enlarged plan view of a structure of heat dissipating fans disposed on a chassis unit shown in FIG. 1; and

FIG. 4 illustrates a schematic diagram of an implementation of a heat dissipating fan system of a plasma display module according to the present invention.

### DETAILED DESCRIPTION OF THE INVENTION

Korean Patent Application No. 10-2005-0030714, filed on Apr. 13, 2005, in the Korean Intellectual Property Office, and entitled: “Plasma Display Model,” is incorporated by reference herein in its entirety.

The present invention will now be described more fully hereinafter with reference to the accompanying drawings, in which exemplary embodiments of the invention are shown. The invention may, however, be embodied in different forms and should not be construed as limited to the embodiments set forth herein. Rather, these embodiments are provided so that this disclosure will be thorough and complete, and will fully convey the scope of the invention to those skilled in the art. In the figures, the dimensions of layers and regions are exaggerated for clarity of illustration. It will also be understood that when a layer is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

A plasma display module according to the present invention provides for efficient heat dissipation of heat generated from a plasma display panel to the outside using forced ventilation. In particular, the temperature of the plasma display panel may be effectively controlled using forced ventilation, thereby enabling the operation of the plasma display module for an extended life span.

The plasma display module may include a chassis having at least one hole therein, and having at least one heat dissipating fan corresponding to the hole. The fan may be mounted substantially parallel with the chassis. The rotational speed of the fan, i.e., the revolutions per minute (RPM), may be controlled so as to effect cooling while reducing unnecessary power consumption and noise generation.

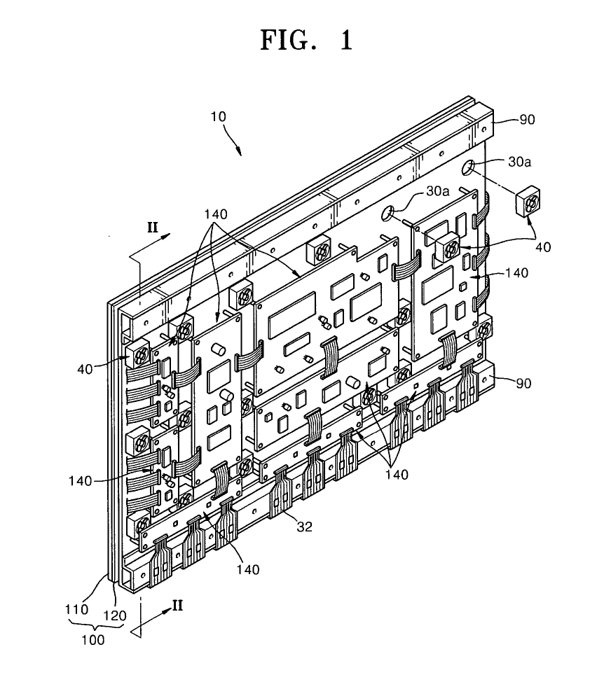

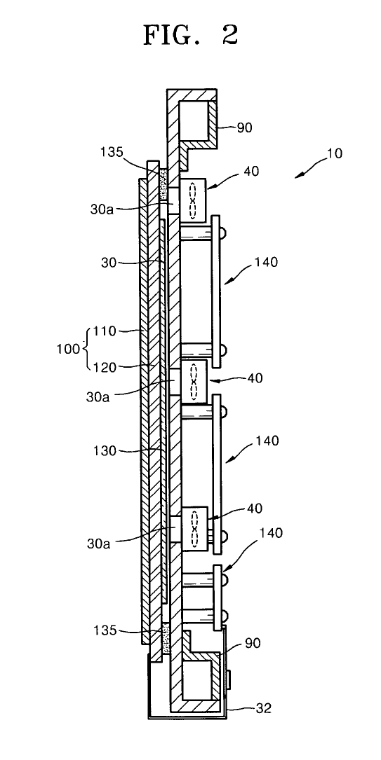

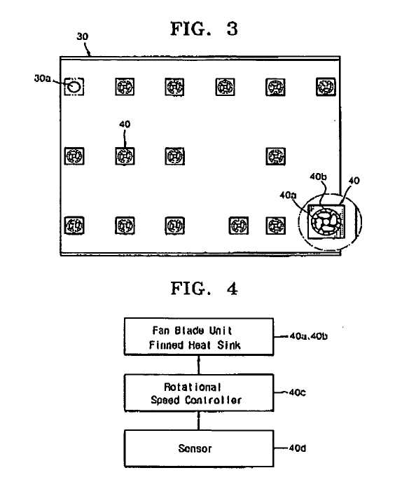

FIG. 1 illustrates a perspective view of a plasma display module according to an embodiment of the present invention, FIG. 2 illustrates a partial cross-sectional view taken along line II-II shown in FIG. 1 and FIG. 3 illustrates a partial enlarged plan view of a structure of heat dissipating fans disposed on a chassis unit shown in FIG. 1.

Referring to FIGS. 1-3, a plasma display module 10 according the present embodiment may include a plasma display panel 100, which may be any one of various kinds of plasma display panels. For example, the plasma display panel 100 may be a three-electrode AC surface discharge plasma display panel.

The plasma display panel 100 may include a first panel 110 and a second panel 120. The first panel 110 may include a plurality of pairs of sustain electrodes, including common electrodes and scan electrodes, which are disposed on a first substrate in a striped pattern, a first dielectric layer for covering the sustain electrode pairs, and a protective layer coated on a surface of the first dielectric layer (not shown). The second panel 120 may be arranged to face the first panel 110, and may include a plurality of address electrodes arranged on a second substrate to be perpendicular to the sustain electrode pairs, a second dielectric layer for covering the address electrodes, partition walls formed on the second dielectric layer to define discharge cells in which discharge is generated and to prevent cross talk, and phosphor layers of red, green and blue which are coated in discharge spaces partitioned by the partition walls (not shown). The discharge cells may correspond to spaces between the sustain electrode pairs and the address electrodes, respectively, and may have a discharge gas filled therein.

A chassis 30 may be disposed on a surface of the plasma display panel 100. The chassis 30 may support the plasma display panel 100 and may serve to prevent the plasma display panel 100 from being deformed by heat or damaged by external impact. The plasma display panel 100 and the chassis 30 may be attached to each other by an adhesive member 135, e.g., a double sided tape. In order to reinforce the rigidity of the chassis 30, the plasma display module 10 may include a reinforcing member 90 which may be disposed on a surface of the chassis 30 opposite to the plasma display panel 100. Additional details of the chassis 30 will be described below.

One or more driving circuit units 140 may be mounted on a surface of the chassis 30 opposite to the plasma display panel 100. The driving circuit unit 140 may generate electrical signals for driving the plasma display panel 100. In particular, the driving circuit unit 140 may include various electronic components (not shown) to apply voltage signals to the plasma display panel 100 for displaying an image, and may supply power. The driving circuit unit 140 may be electrically connected to the plasma display panel 100 through signal transmitting units 31 and 32. The signal transmitting units 31 and 32 may be, e.g., flexible printed cable (FPC) units, tape carrier package (TCP) units, chip on film (COF) units, etc.

The plasma display module 10 may include provisions for active cooling. In an embodiment, at least one hole 30a may be formed in the chassis 30 and at least one corresponding heat dissipating fan 40 may be disposed on the hole 30a, opposite to the plasma display panel 100.

The hole 30a may be formed in a region of the chassis 30 that is not occupied by a driving circuit unit 140, so as to provide a clean air flow path for the corresponding heat dissipating fan 40. Of course, if desired, the layout of the driving circuit units 140 may be adjusted to accommodate the hole/fan pairs. The hole 30a may have a circular shape, as illustrated in the drawings, although the present invention is not limited to this shape, and the hole 30a may be formed in various shapes including, e.g., rectangular, pentagonal, elliptical, etc. The hole 30a may be made as large as practicable, and/or multiple holes 30a may be provided, keeping in mind the requirements for convenient layout of the driving circuit unit 140 and ensuring the rigidity of the chassis 30.

The heat dissipating fan 40 may include a fan blade unit 40a and a motor (not show). The heat dissipating fan 40 may be disposed substantially disposed in parallel with the chassis 30. Disposing the heat dissipating fan 40 substantially in parallel with the chassis 30 includes disposing the heat dissipating fan 40 to be slightly inclined from the chassis 30 as well as disposing the heat dissipating fan 40 to be perfectly in parallel with the chassis 30. Moreover, the present invention is not limited to this arrangement, and, as long as the effect is suitable, the heat dissipating fan 40 may be disposed in any direction.

As described, the heat dissipating fan 40 may be employed to circulate air in a space defined in front of the chassis 30 and behind the plasma display panel 100, i.e., the space formed between the chassis 30 and the plasma display panel 100, or, when a heat dissipating sheet 130 is mounted (see FIG. 2), a space between the chassis 30 and the heat dissipating sheet 130.

The heat dissipating sheet 130 may have good thermal conductivity and may be interposed between the plasma display panel 100 and the chassis 30. Heat generated by the plasma display panel 100 may be transferred to the chassis 30 directly or using the heat dissipating sheet 130 as the thermal conductive medium. The heat dissipating sheet 130 may be disposed such that one surface thereof contacts the plasma display panel 100 and the other surface thereof does not contact the chassis 30. Thus, a predetermined space may be defined between the heat dissipating sheet 130 and the chassis 30. Forced ventilation may be generated through the predetermined space using one or more heat dissipating fans 40 to realize efficient heat dissipation. Although the heat dissipation deteriorates slightly, the heat dissipating sheet 130 may also be disposed such that one surface thereof contacts the plasma display panel 100 and a portion or the whole of the other surface thereof contacts the chassis 30.

The heat dissipating fan 40 may be configured to move air from the open backside of the chassis 30 to the plasma display panel 100, e.g., from the right side in FIG. 2 to the left, into the space defined between the chassis 30 and the heat dissipating sheet 130. The heat dissipating fan 40 may also be configured to move air from the plasma display panel 100 to the chassis 30, e.g., from the space defined between the chassis 30 and the heat dissipating sheet 103 to the right in FIG. 2, to the open backside of the chassis 30. Thus, the heat dissipating fan 40 may circulate the air in the predetermined space formed between the chassis 30 and the plasma display panel 100. One or more heat dissipating fans 40 may be used in each of these implementations, which may be used alone or in combination.

In an implementation, the plasma display module may include at least two heat dissipating fans 40. At least one of the heat dissipating fans 40 may be disposed to send air from the backside of the chassis 30 to the plasma display panel 100, and another one or more of the heat dissipating fans 40 may be disposed to send air from the plasma display panel 100 to the chassis 30. Accordingly, this arrangement may provide air flow from the backside of the chassis 30 to the plasma display panel 100 through a first hole 30a, across the plasma display panel 100 and/or the heat dissipating sheet 130, and then from the plasma display panel 100 out through the chassis 30 through a second hole 30a. Thus, heat generated by the plasma display panel 100 can be smoothly dissipated to the outside using forced ventilation.

FIG. 4 illustrates a schematic diagram of an implementation of a heat dissipating fan system of a plasma display module according to the present invention. Referring to FIG. 4, the plasma display module 10 may further include a sensor 40d, a rotational speed controller 40c, and a finned heat sink 40b, in addition to the fan blade unit 40a and the motor. The sensor 40d may be, e.g., a temperature sensor. The sensor 40d may be used in combination with the rotational speed controller to adjust the speed of the fan motor.

Where, as illustrated in FIG. 2, the heat dissipating sheet 130 is included in the plasma display module 10, the sensor 40d may be disposed to contact the heat dissipating sheet 130 and/or a predetermined portion of the plasma display panel 100 through the chassis 30. However, the present invention is not limited to these arrangements, and the sensor 40d may be disposed at other positions in the plasma display module 10, including within the heat dissipating fan 40.

In another implementation, the sensor 40d may be a sensor such as a noise sensor. Of course, multiple sensors 40d may also be provided to supply temperature, noise, and other information.

The rotational speed controller 40c may receive data from the sensor 40d and use the data to control the rotational speed of the fan 40a. For example, the rotational speed control 40c may use a variable resistor to control the motor speed, e.g., to continuously vary the motor speed between two predetermined speeds such as maximum and off, or it may adjust the motor speed to one of a plurality of predetermined motor speeds, e.g., maximum, medium, and off, etc. The rotational speed controller 40c may be disposed in any suitable location in the plasma display module 10, including within the heat dissipating fan 40.

As the temperature of the plasma display panel 100 varies, e.g., due to operation of the plasma display panel 100 and/or the temperature of the surrounding environment, the rotational speed of the fan blade unit 40a may be correspondingly controlled. In an implementation, the when a high level of cooling is not required, the sensor 40d and the rotational speed controller 40c may be used to reduce the rotational speed of the fan blade unit 40a and motor, in order to reduce unnecessary noise and power consumption by the heat dissipating fan 40.

In particular, when the operating conditions of the plasma display module 10 are such that little heat is generated, and/or the ambient temperature is sufficiently low, e.g., during winter or in an air conditioned environment, the fan 40a need not operate, and heat dissipation may be effected using passive, i.e., unforced convection. In another implementation, if the ambient environment is quiet, the fan 40a may operate in a low-noise mode, e.g., at a low rotational speed, while, if the environment is noisy, the fan 40a may operate at a higher rotational speed. The rotational speed may be controlled based on the difference between the ambient noise levels and fan-generated noise, such that the heat dissipating fan 40 generates noise at a level that is less than, or not appreciably noticeable in view of, the ambient noise. Thus, the rotational speed control 40c may decrease the speed of the heat dissipating fan 40 when the sensor 40d senses decreasing temperature, noise, etc. Accordingly, the present invention may provide the advantages of forced ventilation without excessive power consumption and/or without generation of excessive noise.

The plasma display module 10 may include the finned heat sink 40b, i.e., a heat sink with one or more fins, to further enhance heat dissipation. In an implementation, the finned heat sink 40b may be incorporated into the heat dissipating fan 40, e.g., on a head (not shown) positioned on a rear surface of the heat dissipating fan 40, to aid the heat dissipation of the fan blade unit 40a. The shape, a position, and a mounting angle of the finned heat sink 40b may be determined such that a maximum heat dissipating area can be ensured with respect to air which flows therein from a front side of the heat dissipating fan 40.

Exemplary embodiments of the present invention have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A plasma display module, comprising:
a plasma display panel for displaying a visible image;
a chassis supporting the plasma display panel and having at least one hole therein; and
at least one heat dissipating fan disposed to face the at least one hole.

2. The plasma display module as claimed in claim 1, further comprising a driving circuit unit for generating electrical signals for driving the plasma display panel, wherein:
the driving circuit unit is disposed on a surface of the chassis opposite to the plasma display panel, and
the at least one hole is formed in a portion of the chassis in which the driving circuit unit is not disposed.

3. The plasma display module as claimed in claim 1, wherein the heat dissipating fan is disposed substantially in parallel with the chassis.

4. The plasma display module as claimed in claim 1, wherein the heat dissipating fan is disposed to circulate air in a space defined between the chassis and the plasma display panel.

5. The plasma display module as claimed in claim 4, wherein the heat dissipating fan is disposed to send the air from an opposite side of the chassis to the space.

6. The plasma display module as claimed in claim 4, wherein the heat dissipating fan is disposed to send the air from the space to an opposite side of the chassis.

7. The plasma display module as claimed in claim 4, wherein the plasma display module includes at least two heat dissipating fans,
at least one of the two heat dissipating fans is disposed to send air from an opposite side of the chassis to the space, and
at least one other of the two heat dissipating fans is disposed to send air from the space to the opposite side of the chassis.

8. The plasma display module as claimed in claim 1, further comprising a thermally conductive heat dissipating sheet interposed between the plasma display panel and the chassis and arranged such that the at least one heat dissipating fan can circulate air between the heat dissipating sheet and the chassis.

9. The plasma display module as claimed in claim 8, wherein one surface of the heat dissipating sheet contacts the plasma display panel and the other surface thereof does not contact the chassis, such that air circulated by the fan can travel across the other surface.

10. The plasma display module as claimed in claim 1, further comprising:
a sensor; and
a rotational speed controller configured to receive data from the sensor and control a rotational speed the heat dissipating fan.

11. The plasma display module as claimed in claim 10, wherein the sensor and the rotational speed controller are part of the heat dissipating fan.

12. The plasma display module as claimed in claim 11, wherein the heat dissipating fan further includes a finned heat sink.

13. The plasma display module as claimed in claim 10, wherein the sensor is a temperature sensor.

14. The plasma display module as claimed in claim 13, wherein the rotational speed controller is configured to decrease the rotational speed of the heat dissipating fan when the temperature sensor senses a decreasing temperature.

15. The plasma display module as claimed in claim 10, wherein the sensor is a noise sensor.

16. The plasma display module as claimed in claim 15, wherein the rotational speed controller is configured to decrease the rotational speed of the heat dissipating fan when the noise sensor senses a decreasing level of noise.

17. The plasma display module as claimed in claim 10, wherein the rotational speed controller is configured to continuously vary the rotational speed of the heat dissipating fan between a first speed and a second speed.

18. The plasma display module as claimed in claim 10, wherein the rotational speed controller is configured to set the rotational speed of the heat dissipating fan to one of at least three predetermined rotational speeds.
